(19) United States
(12) Patent Application Publication
(10) Pub. No.: US 2026/0255542 A1
(43) Pub. Date: Aug. 27, 2026

(54) TWO-PHASE IMMERSION COOLING SYSTEMS FOR ELECTRONICS, AND ASSOCIATED DEVICES AND METHODS

(71) Applicant: BLUEXTHERMAL, INC., Cambridge, MA (US)

(72) Inventor: Nicholas Keith Anselmo, Yorktown, VA (US)

(21) Appl. No.: 19/546,169

(22) Filed: Feb. 20, 2026

Related U.S. Application Data
(60) Provisional application No. 63/761,403, filed on Feb. 21, 2025.

(51) Int. Cl. H05K 7/20

(52) U.S. Cl. CPC H05K 7/203; H05K 7/20327

(57) ABSTRACT

Two-phase immersion cooling systems for electronics are disclosed herein. In some embodiments, a device includes a base having a first side and a second side, and a plurality of blades each coupled to and extending from the second side of the base along an axis substantially normal to an outer surface of the second side. Individual ones of the blades (i) include first through fourth sides, (ii) are spaced apart from one another such that fluid can flow therebetween, and (iii) include a plurality of microfeatures at the third and/or fourth sides of the respective blade. The microfeatures increase an exposed surface area of the respective blade and adjacent microfeatures define microchannels therebetween. Individual ones of the microchannels extend along the axis and have a width between 1 femtometer and 1 millimeter. The base and the blades are configured to be submerged in a cooling fluid.

### CROSS-REFERENCE TO RELATED APPLICATION(S)

The present application claims the benefit of U.S. Provisional Patent Application No. 63/761,403, filed Feb. 21, 2025, the disclosure of which is incorporated herein by reference in its entirety.

### TECHNICAL FIELD

The present technology generally relates to cooling systems and, in particular, to two-phase immersion cooling systems for electronics, and associated devices and methods.

### BACKGROUND

Cooling systems have become increasingly critical as computing densities rise and generative Artificial Intelligence (AI) workloads drive sustained, high-power operation in modern data centers. Advanced processors, including GPUs and specialized accelerators, generate significant heat under continuous parallel computation, straining conventional air-cooling approaches and increasing the risks of thermal throttling, reliability degradation, and inefficiency. In particular, housing many servers together in a shared space can exacerbate thermal management issues. To maintain performance and uptime while meeting stricter energy and sustainability targets, operators require more effective heat-removal architectures. Accordingly, there is a growing need for improved cooling solutions that enhance heat transfer, increase efficiency, and enable higher rack densities.

### BRIEF DESCRIPTION OF THE DRAWINGS

Many aspects of the present disclosure can be better understood with reference to the following drawings. The components in the drawings are not necessarily to scale. Instead, emphasis is placed on illustrating clearly the principles of the present disclosure. The drawings should not be taken to limit the disclosure to the specific embodiments shown, but are provided for explanation and understanding.

FIG. 1 is a perspective view of a two-phase immersion cooling system configured in accordance with various embodiments of the present technology.

FIG. 2 is a perspective view of a two-phase immersion cooling device configured in accordance with various embodiments of the present technology.

FIGS. 3A and 3B illustrate operation of the two-phase immersion cooling device of FIG. 2 in accordance with various embodiments of the present technology.

FIG. 4 is a perspective view of the two-phase immersion cooling device of FIG. 2 during operation in accordance with various embodiments of the present technology.

FIG. 5 is a cross-sectional side view of a single-pool immersion cooling system configured in accordance with various embodiments of the present technology.

FIG. 6 is a cross-sectional side view of a multi-pool immersion cooling system configured in accordance with various embodiments of the present technology.

FIGS. 7A and 7B are perspective views of an actuatable two-phase immersion cooling device configured in accordance with various embodiments of the present technology.

FIG. 8 is a perspective view of another actuatable two-phase immersion cooling device configured in accordance with various embodiments of the present technology.

FIG. 9 is a perspective view of a variable-width two-phase immersion cooling device configured in accordance with various embodiments of the present technology.

FIG. 10 is a perspective view of another variable-width two-phase immersion cooling device configured in accordance with various embodiments of the present technology.

FIG. 11 is a perspective view of a feeder two-phase immersion cooling device configured in accordance with various embodiments of the present technology.

FIG. 12 is a flowchart illustrating a method for cooling electronics in accordance with various embodiments of the present technology.

### DETAILED DESCRIPTION

### I. Overview

The present technology is generally directed to two-phase immersion cooling systems that can cool electronics via continuous thin-film evaporation. Many cooling systems, including single-phase systems and two-phase systems, are being used worldwide to cool various electronics. These existing systems, however, face several operational limitations. For example, single-phase cooling systems, which rely on sensible heat transfer without phase change, are constrained by relatively low heat-transfer coefficients, higher temperature gradients across components, and the need for high flow rates and larger heat exchangers to manage hotspots—often resulting in increased pumping power, noise, and space consumption. As another example, two-phase cooling systems, including pumped mixed-phase and nucleated boiling approaches, can deliver higher heat flux removal but remain susceptible to “dry-outs” and may not provide heat transfer coefficients that can keep up with the growing demand for cooling solutions. “Dry-outs” refer to the loss or depletion of the liquid film at the evaporating surface in a two-phase cooling system, compromising the effectiveness of the cooling.

Embodiments of the present technology address at least some of the above described issues. For example, embodiments of the present technology include two-phase immersion cooling devices that can be attached to electronics and submerged with the electronics in an immersion cooling pool. The two-phase immersion cooling devices can maintain a vapor region close to the electronics, draw in the cooling fluid toward the vapor region, and evaporate the cooling fluid at a meniscus via thin-film evaporation. High heat transfer can occur at the meniscus due to the small temperature gradient across the nanometer-to-micrometer-scale liquid layer, enabling rapid phase change without bubble nucleation. Thus, embodiments of the present technology can yield high heat flux capability in a compact, low-profile form factor and avoids instability modes common in boiling (e.g., dry-outs).

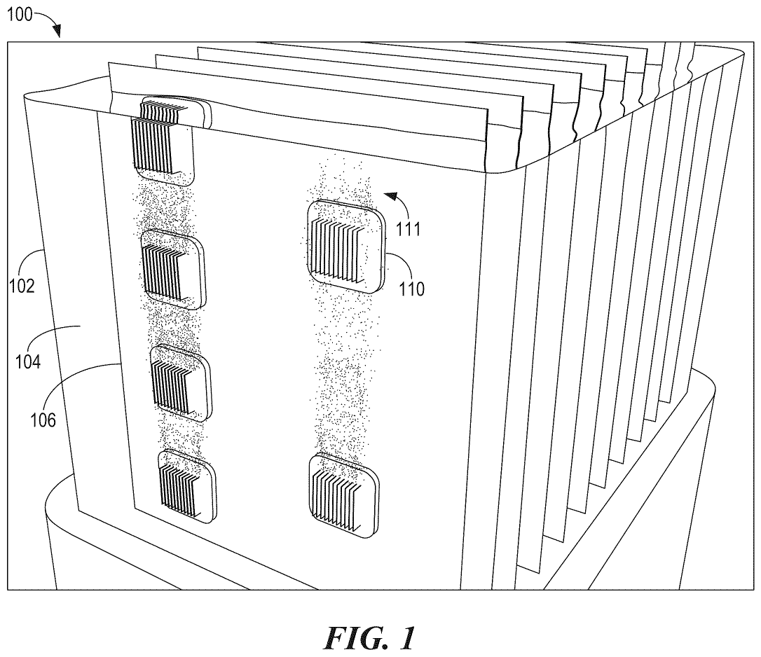

In the following description, specific details are set forth to provide a thorough understanding of aspects of the present technology. One skilled in the relevant art will recognize, however, that the systems, devices, and techniques described herein can be practiced without one or more of the specific details set forth herein, or with other methods, components, materials, etc. The terminology used in the description presented below is intended to be interpreted in its broadest reasonable manner, even though it is being used in conjunction with a detailed description of certain specific embodiments of the present technology. Certain terms may even be emphasized below; however, any terminology intended to be interpreted in any restricted manner will be overtly and specifically defined as such in this Detailed Description section. Additionally, the present technology can include other embodiments that are within the scope of the examples or claims but are not described in detail with respect to FIGS. 1-12.

Reference throughout this specification to an “example” or an “embodiment” means that a particular feature, structure, or characteristic described in connection with the example or embodiment is included in at least one example or embodiment of the present technology. Thus, use of the phrases “for example,” “as an example,” or “an embodiment” herein are not necessarily all referring to the same example or embodiment and are not necessarily limited to the specific example or embodiment discussed. Furthermore, features, structures, or characteristics of the present technology described herein may be combined in any suitable manner to provide further examples or embodiments of the present technology.

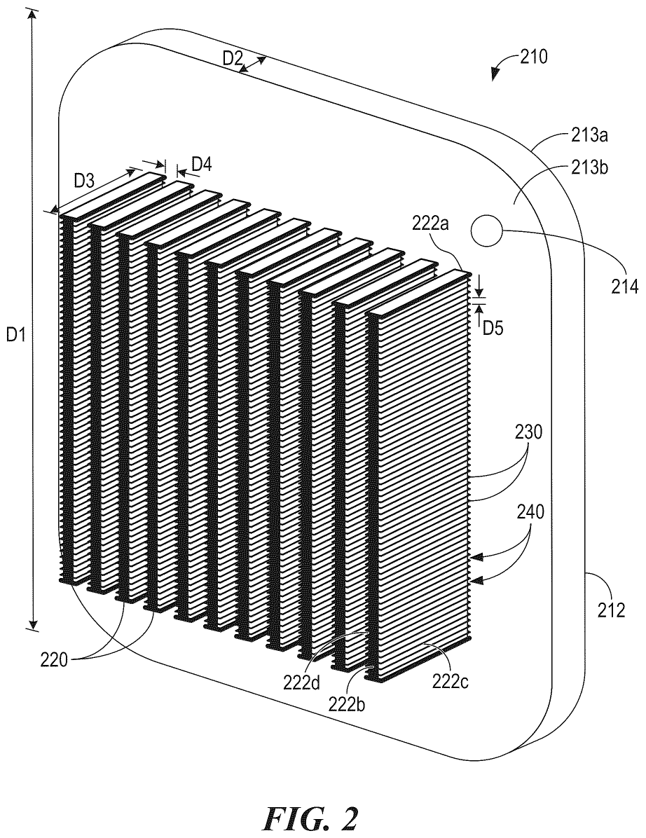

Reference numbers used in the figures of the present disclosure follow a numbering convention in which (i) the first digit or digits correspond to the first figure in which a particular element or component is introduced and (ii) the remaining digits identify that particular element or component in the figures. Unless otherwise specified or made clear from context, similar references numbers are used across multiple figures to denote generally similar and/or identical components. For example, reference number 102 can be used to reference an element “2” that was first introduced in FIG. 1. Use of reference number 102 in FIG. 2 can identify the element “2” from FIG. 1 in FIG. 2. Use of reference number 202 in FIG. 2 can be used to reference an element “2” that was first introduced in FIG. 2, and that may (depending on context) be generally similar and/or identical to the element “2” corresponding to reference number 102 that was first introduced in FIG. 1.

The headings provided herein are for convenience only and are not to be used to interpret the scope of the claimed technology.

### II. Select Embodiments of a Two-phase Immersion Cooling System

FIG. 1 is a perspective view of a two-phase immersion cooling system 100 (“the system 100”) configured in accordance with various embodiments of the present technology. The system 100 can include (or be configured to be immersed in) an immersion cooling pool 102 filled with a cooling fluid 104, one or more electronics 106 at least partially submerged in the cooling fluid 104, and one or more two-phase immersion cooling devices 110 (“the devices 110”) coupled to the electronics 106.

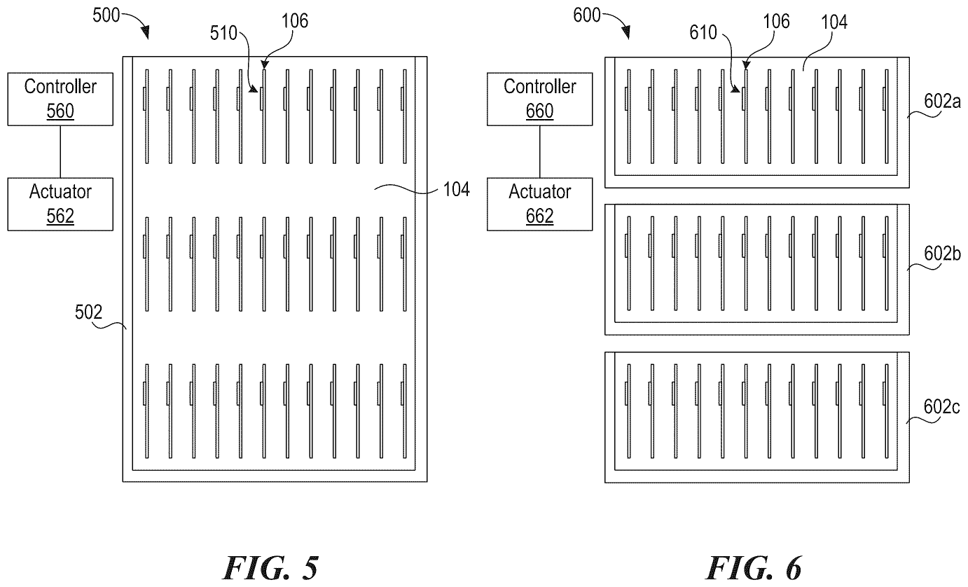

The immersion cooling pool 102 can have various shapes and sizes, and the illustrated embodiment is merely one example. Additional configurations of immersion cooling pools are illustrated in and described below with reference to FIGS. 5 and 6. The cooling fluid 104 can include water, oils, dielectric fluids, metals, octane, hydrocarbons, pentane, R-245ca, R-245fa, iso-pentane, halogenated hydrocarbons, perfluoroalkanes, halogenated alkanes, ketones, alcohols, alkali metals, and/or other suitable substances. For example, additives can be added to water to alter thermal conductivity, electrical conductivity, and/or the like.

The electronics 106 can include servers, motherboards, chips, and/or other heat-generating components. In the illustrated embodiment, the electronics 106 include circuit boards arranged in parallel. In some embodiments, each circuit board can include multiple heat-generating processing unit chips (e.g., CPUs, GPUs; obscured from view in FIG. 1) and the devices 110 can be coupled to corresponding ones of the heat-generating chips via adhesives, fasteners, and/or other suitable coupling mechanisms. As discussed in greater detail herein, in operation, the devices 110 can passively cool the electronics 106 (e.g., without thermoelectric components (TECs), without pumps) by maintaining a vapor region close to the electronics 106, drawing in the cooling fluid 104 toward the vapor region (e.g., via capillary action), and evaporating the cooling fluid at a meniscus via thin-film evaporation. The generated vapor can rise up through the cooling fluid 104 as bubbles 111.

FIG. 2 is a perspective view of a two-phase immersion cooling device 210 (“the device 210”) configured in accordance with various embodiments of the present technology. The device 210 can be an example of one of the devices 110 of FIG. 1. The device 210 can include a base 212 and a plurality of blades 220 coupled to the base 212. In some embodiments, the device 210 also includes one or more sensors 214 (illustrated schematically as a circle in FIG. 2) such as a temperature sensor, a heat flux sensor, a pressure sensor, and/or the like. The sensors 214 can be coupled to the base 212, as shown.

The base 212 can be a generally planar component that can be coupled to electronics. The specific shape and size of the base 212 can be selected (e.g., prior to attaching the device 210 to the electronics) based on the physical parameters and the thermal needs specific to the electronics to be cooled. In some embodiments, the base 212 is sized to be generally similar to or larger than an individual heat-generating chip (e.g., CPU, GPU). The base 212 can include a first side 213a that can be attached to such a chip, and a second side 213b opposite the first side 213a. Each edge of the base 212 can have a length D1 between 1-100 millimeters (mm) or between 10-30 mm, and the thickness D2 of the base 212 can be no more than 10 mm, 5 mm, 3 mm, or 1 mm. In some embodiments, the surface of the base 212 is texturized (e.g., undulating, dimpled, roughened), such as by sandblasting, to provide surface geometry sufficient to maintain contact with electronics.

The blades 220 can extend from a side of the base 212 in a direction substantially normal to an outer surface of the second side 213b of the base 212. Specifically, individual ones of the blades 220 can have (i) a first side 222a coupled to the second side 213b of the base 212, (ii) a second side 222b opposite the first side 222a, (iii) a third side 222c extending between the first side 222a and the second side 222b, and (iv) a fourth side 222d opposite the third side 222c and extending between the first side 222a and the second side 222b of the individual ones of the blades 220. The blades 220 can have generally thin form factors (e.g., generally planar) and can be spaced apart from one another in a parallel arrangement.

The length D3 of each blade 220 (extending away from the base 212) can be at least 1 mm, 2 mm, 4 mm, 6 mm, 8 mm, 10 mm, or more. The spacing D4 between the blades 220 can be uniform or can vary to meet specific cooling demands, and can be, e.g., between 20 microns and 1 mm. Also, each blade 220 can include a plurality of microfeatures 230 on either or both faces thereof. In the illustrated embodiment, the microfeatures 230 include elongate protrusions having rectangular cross-sections and extending along both faces of the respective blade 220 in a direction substantially normal to the base 212. The number of microfeatures 230 on each face of each blade 220 can be at least 2, 5, 10, 20, 30, 40, 50, or more. Moreover, the microfeatures 230 can be spaced apart from one another in a parallel arrangement so as to define a plurality of open microchannels 240 also extending in a direction substantially normal to the base 212. As shown, the microchannels 240 can be open at the distal end of the respective blade 220 and extend all the way to the base 212.

The base 212 and the blades 220, including the microfeatures 230, can be composed of metal (e.g., copper, aluminum, steel), silicon, and/or other suitable material that can withstand and efficiently transfer the heat generated by electronics, and is non-reactive with the particular cooling fluid in use. In some embodiments, the base 212 and the blades 220 are integrally formed, such as via casting, etching, waterjet cutting, laser ablation, or additive manufacturing (e.g., 3D printing). In some embodiments, the blades 220 are separate components that are attached to the base 212, such as via welding.

In operation, the base 212 can conduct the heat generated by electronics to the blades 220 and the cooling fluid, and the blades 220 can further conduct the heat from the base 212 to the cooling fluid. Notably, the blades 220, by virtue of their thin form factors and the shapes of the microfeatures 230, provide a large amount of surface area through which heat can be transferred to the cooling fluid. Also, the microfeatures 230 can be shaped and sized such that the microchannels 240 can move the cooling fluid therethrough via capillary action. For example, the width D5 of each microchannel 240 can be between 1 femtometer (Fm) and 1 mm (e.g., about 100 nanometers (nm), about 100 microns, between 100 nm and 100 microns). As discussed in greater detail herein, the capillary action can help draw the cooling fluid toward an area where the cooling fluid can evaporate via thin-film evaporation. Also, notably, the blades 220 are cantilevered blades connected to one another only at the base 212, providing minimal obstruction to liquid entering the microchannels 240 or vapor rising from the device 210.

It is appreciated that the device 210 of FIG. 2 is merely an illustrative example, and that other embodiments of the present technology can include fewer, additional, and/or alternative components. For example, the microfeatures 230 of the present technology can be elongate protrusions having triangular, rounded, or other cross-sections, pins (e.g., arranged in a grid pattern), projections, walls with fractal patterns, and/or the like. As another example, the length of the blades 220 can vary based on the physical parameters and the thermal needs specific to the electronics to be cooled. As yet another example, the microfeatures 230 need not be included in each and every face of the blades 220 and may, e.g., be included only on the outermost faces of the outermost blades 220 that do not face any other blade 220. As yet another example, the base 212 can be omitted such that the blades 220 can directly contact electronics, and the blades 220 can be coupled to the electronics and one another via connections positioned away from where the blades 220 contact the electronics. As yet another example, the blades 220 can be composed of a porous material in which the porous structure are the microfeatures and the pores are the microchannels.

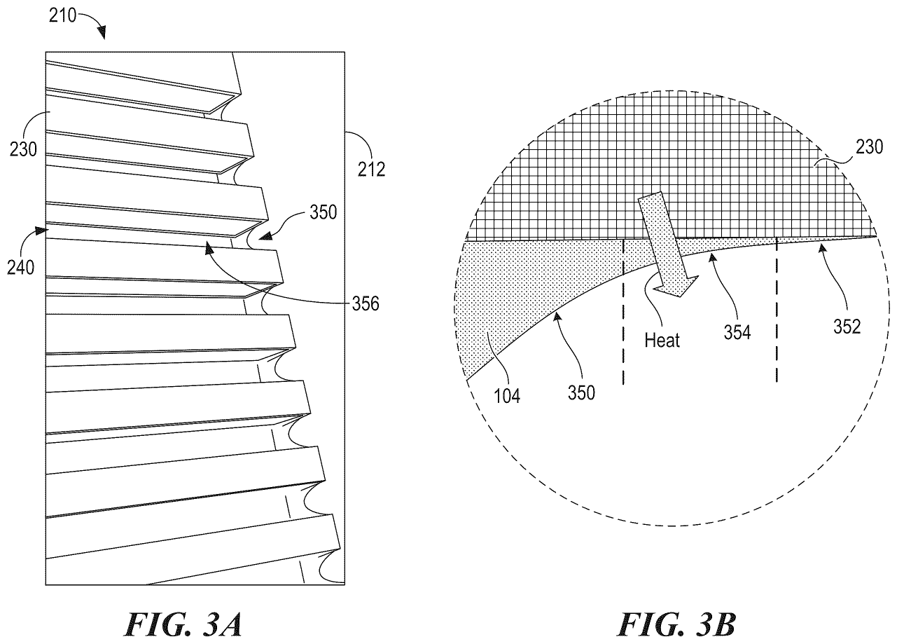

FIGS. 3A and 3B illustrate operation of the two-phase immersion cooling device 210 in accordance with various embodiments of the present technology. Referring first to FIG. 3A, which is an enlarged perspective view of the interface between the microfeatures 230 and the base 212, the cooling fluid 104 is shown in the microchannels 240. The cooling fluid 104 can form a meniscus 350 on the surface of the base 212 by virtue of the shape, size, and material of the microfeatures 230, surface forces, the temperature gradient (e.g., the base 212 is where the temperature is highest along the length of the microchannels 240), etc. Because the meniscus 350 is formed on the surface of the base 212, a significant portion of the base 212 may remain in contact with the cooling fluid in the vapor phase as opposed to the liquid phase (e.g., remains “dry,” or more accurately, remains “moist” as opposed to “wet”).

Referring momentarily to FIG. 3B, which is an enlarged partial view of the meniscus 350, the meniscus 350 can include a non-evaporating thin-film region 352 and an evaporating thin-film region 354. The non-evaporating thin-film region 352 can be at the edge of the meniscus 350 where the layer of the cooling fluid 104 is thin and adhesion forces between the liquid molecules of the cooling fluid 104 and the solid surface of the microfeatures 230 are extremely strong. Thus, little to none of the liquid molecules of the cooling fluid 104 may be able to escape the liquid phase into the vapor phase (e.g., notwithstanding the heat from the base 212). In contrast, the evaporating thin-film region 354 can be positioned closer to the center of the meniscus 350 where the layer of the cooling fluid 104 is still thin but adhesion forces between the liquid molecules of the cooling fluid 104 and the solid surface of the microfeatures 230 are weaker. Thus, the liquid molecules of the cooling fluid 104 can able to escape the liquid phase into the vapor phase upon receiving the heat from the base 212.

The evaporating thin-film region 354 is where the bulk of evaporative heat transfer takes place due to the very low thickness and conductive resistance. Thus, the evaporating thin film region represents the region of optimal evaporation and heat transfer. One advantage of thin-film evaporation is the elimination or reduction of boiling, and thus can start with less heat. In particular, the microfeatures 230 can be designed to specifically avoid or minimize the risk of initiating boiling, which can not only be less thermally efficient but also disrupt thin-film evaporation. As heat travels through the base 212 and the microfeatures 230, the initial vapor generated can flush out liquid and begin forming a vapor region. In particular, once the vapor pressure overcomes the hydrostatic pressure, the device 210 can maintain steady-state operation in which heat is conducted directly to the evaporating thin-film region 354 of the meniscus 350 where the bulk of evaporative heat transfer takes place. In this manner, the risk of boiling within the channel is eliminated and the ordered and efficient evaporation can be maintained continually. It is further advantageous that the evaporating thin-film region 354 and the meniscus 350 as a whole are at or near the base 212, enabling successful and efficient heat transfer to the evaporating thin-film region 354 compared to, e.g., other embodiments in which the meniscus 350 is removed from the base 212.

Moreover, even if the device 210 is rotated to various orientations, the size scale of the microfeatures 230 and the meniscus 350 can be sufficiently small such that surface forces dominate and the meniscus 350 remains in the illustrated shape and orientation with respect to the microfeatures 230 notwithstanding the direction of gravity. Additional details regarding the meniscus and, in particular, thin-film evaporation are provided in U.S. patent application Ser. No. 16/936,358, issued as U.S. Pat. No. 11,768,016, titled “THERMAL MANAGEMENT DEVICE AND SYSTEM,” and filed on Jul. 22, 2020, the disclosure of which is incorporated by reference herein in its entireties.

Returning to FIG. 3A, because the device 210 is submerged in the cooling fluid 104 and a significant portion of the temperature gradient does not extend along the entire length of the microchannels 240, the meniscus 350 does not extend along the entire length of each microchannel 240. Rather, the microchannels 240 can be filled with the cooling fluid 104 closer to the distal ends of the blades 220 and gradually transition to the meniscus 350 toward the base 212. For example, the cooling fluid 104 may have a transition portion 356 in which the cooling fluid 104 has a curved, contoured, and/or sloped surface that transitions to the shape of the meniscus 350. In some embodiments, the transition portion 356 generally defines a boundary between a liquid region and a vapor region. For example, thin-film evaporation can occur along at least parts of the transition portion 356. The location of the transition portion 356 along the length of the blades 220 can depend on several different factors such as, for example, the temperature gradient (e.g., affected by the heat generated by the electronics and the temperature of the cooling fluid) and the physical properties of the cooling fluid (e.g., density which can affect hydrostatic pressure, thermal conductivity, adhesion to surfaces).

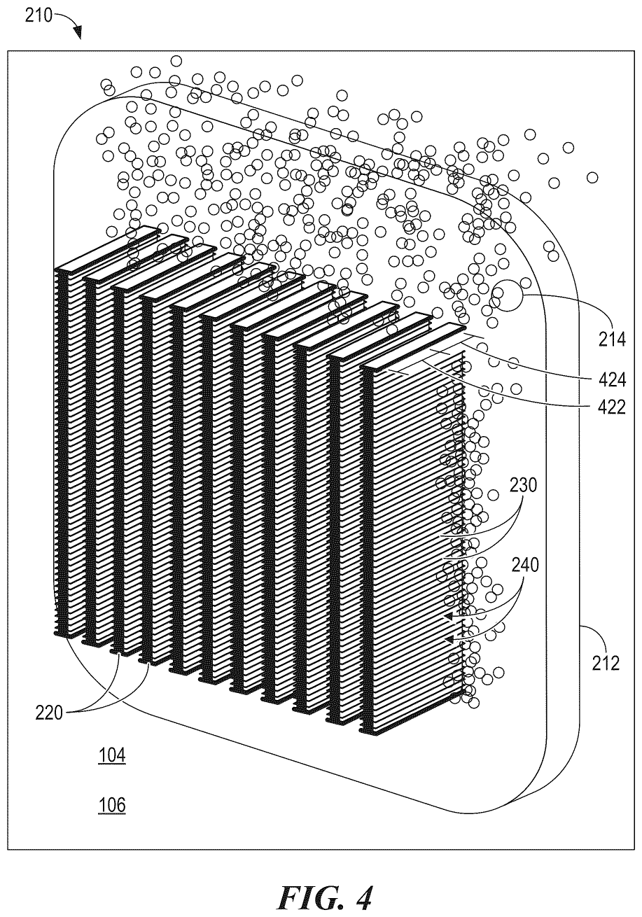

FIG. 4 is a perspective view of the two-phase immersion cooling device 210 during operation in accordance with various embodiments of the present technology. As shown, the base 212 can be coupled to (e.g., in direct contact with) the electronics 106 (e.g., to a GPU chip thereof). As the electronics 106 generate heat, the temperature gradient resulting from the heat and the microfeatures 230 can define (i) a liquid region 422 extending along the length of the blades 220 from the distal ends thereof and (ii) a vapor region 424 extending along the length of the blades 220 between the liquid region 422 and the base 212.

The liquid region 422 can be where the cooling fluid 104 is in the liquid phase and the microfeatures 230 move the cooling fluid 104 along the microchannels 240 toward the vapor region 424 via capillary action. Thus, the capillary forces generated by the microfeatures 230 can continuously supply the cooling fluid 104 in the liquid phase for subsequent evaporation and heat transfer. The vapor region 424 can be where the cooling fluid 104 turns into vapor via the thin-film evaporation discussed above with reference to FIG. 3B. As shown in FIG. 4, the vapor can rise and escape as bubbles 411 rising through the cooling fluid 104. In particular, by orienting the device 210 such that the individual blades 220 lie on planes parallel to the direction of gravity, the bubbles 411 can rise through the gaps between the blades 220.

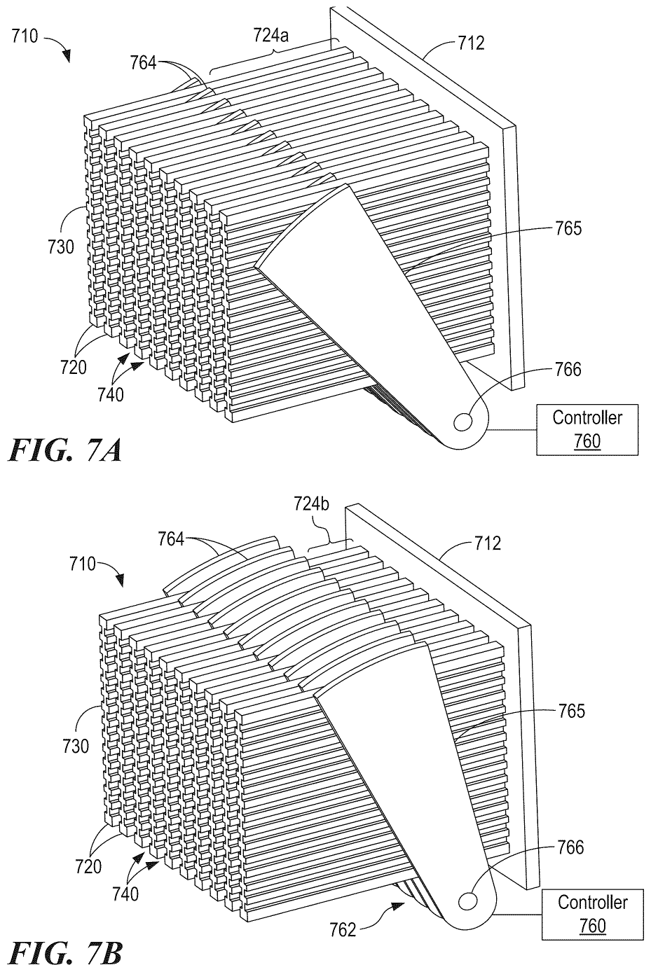

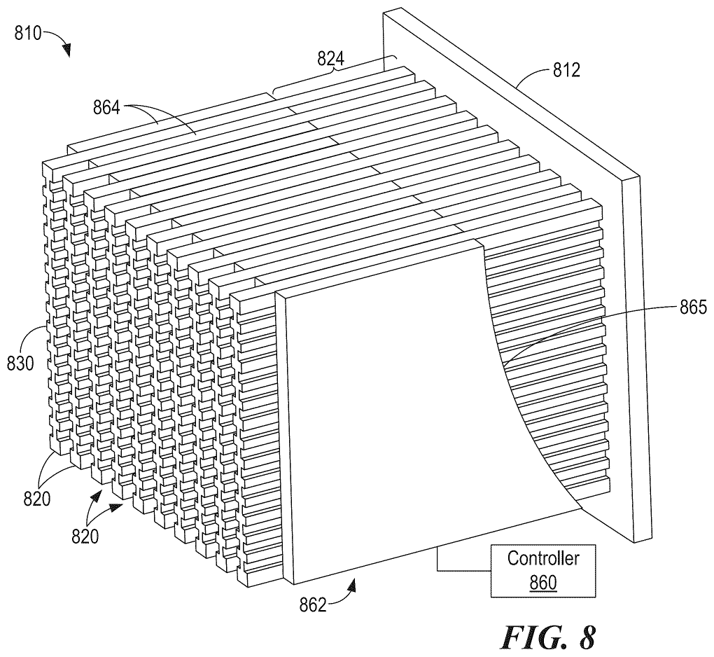

As discussed above with reference to FIG. 3B, both liquid and vapor phases must be present in order for thin-film evaporation to occur in an efficient manner. Accordingly, it can be important to maintain both the liquid region 422 and the vapor region 424 throughout operation. In passive embodiments of the present technology without any controllers or actuators, such as the device 210 of FIGS. 2-4, once operation begins, the presence of the liquid region 422 and the vapor region 424 can depend entirely on the amount of heat generated by the electronics. Therefore, it can be important to accurately anticipate the amount of heat to be generated and select design parameters (e.g., the dimensions of the blades 220, the specific shapes and sizes of the microfeatures 230 and the microchannels 240, the thermal conductivity of the material forming the device 210) that are conducive to maintaining both the liquid region 422 and the vapor region 424. In actuatable embodiments of the present technology, examples of which are illustrated in and described below with reference to FIGS. 7A-8, actuators can help maintain and control the liquid region 422 and the vapor region 424.

FIG. 5 is a cross-sectional side view of a single-pool immersion cooling system 500 (“the system 500”) configured in accordance with various embodiments of the present technology. The system 500 can include an immersion cooling pool 502 filled with the cooling fluid 104, electronics 106 (e.g., circuit boards), and two-phase immersion cooling devices 510 (“the devices 510”). One or more of the devices 510 can be coupled to each of the electronics 106, which are arranged at multiple depths in the cooling fluid 104.

In some embodiments, the system 500 can also include a controller 560 and an actuator 562, both illustrated schematically. In operation, the controller 560 can control the actuator 562 to move one or more of the electronics, and thus the devices 510 attached thereto, within the cooling fluid 104. For example, if electronics 106 at the deepest row are generating the most amount of heat (e.g., as determined by the sensors 214 of FIG. 2), the controller 560 can control the actuator 562 to move those electronics upward closer to the surface of the cooling fluid 104. Doing so can reduce the hydrostatic pressure around those electronics 106 and help achieve a better balance between the hydrostatic pressure and the vapor pressure, which can help maintain the liquid and vapor regions and allow continued thin-film evaporation.

FIG. 6 is a cross-sectional side view of a multi-pool immersion cooling system 600 (“the system 600”) configured in accordance with various embodiments of the present technology. The system 600 can include multiple immersion cooling pools 602a-602c each filled with the cooling fluid 104, electronics 106 (e.g., circuit boards), and two-phase immersion cooling devices 610 (“the devices 610”). Unlike the immersion cooling pool 502 of FIG. 5, each of the immersion cooling pools 602a-602c includes only a single row of electronics 106 at the same depth. Moreover, because the electronics 106 are at a relatively shallow depth, the apparent hydrostatic pressure at each evaporating block can be minimized or at least reduced, thereby reducing the temperature of the evaporation. In some embodiments, the system 600 additionally includes a controller 660 and an actuator 662, operable in the same manner as the controller 560 and the actuator 562, respectively.

Referring to FIGS. 5 and 6 together, the cooling fluid 104 can remain stagnant in the immersion cooling pool(s) or be circulated during operation. In some embodiments, a controller can control the temperature of the cooling fluid 104 based on, e.g., sensor measurements so as to optimize thin-film evaporation. For example, the temperature of the cooling fluid 104 can be varied between −20° C. and 40° C. Moreover, during operation, the vapor generated can rise up, naturally cool down above the surface level of the cooling fluid 104, and condense back into the immersion cooling pool, thereby automatically cycling back with or without an external pump.

FIGS. 7A and 7B are perspective views of an actuatable two-phase immersion cooling device 710 (“the device 710”) configured in accordance with various embodiments of the present technology. Referring to FIGS. 7A and 7B together, the device 710 can include a base 712, a plurality of blades 720, a controller 760 (illustrated schematically), and an actuator 762. Like the blades 220 of FIG. 2, the blades 720 can be coupled to and extend from the base 712 and include microfeatures 730 that define microchannels 740. In the illustrated embodiment, the actuator 762 includes multiple fins 764 each positioned in between adjacent blades 720 and/or adjacent to one of the blades 720.

In operation, the controller 760 can operate the actuator 762 to rotate about a pivot 766. As the actuator 762 pivots, leading edges 765 of the individual fins 764 also pivot. When the actuator 762 is in a first position, as shown in FIG. 7A, the leading edges 765 can define a first vapor region 724a. As shown, the leading edges 765 are at an angle with respect to the direction of gravity such that the vapor region 724a is narrow at the bottom closer to the pivot 766 and wider at the top closer to, e.g., the surface level of the cooling fluid. Accordingly, fewer vapor bubbles may be generated at the bottom than at the top, allowing the vapor bubbles to rise through and escape more easily. When the actuator 762 is in a second position, as shown in FIG. 7A, the leadings edges can define a second vapor region 724b. The leading edges 765 are still at an angle with respect to the direction of gravity. However, the second vapor region 724b is narrower than the first vapor region 724a. The fins 764 can help prevent choking out the vapor region by, e.g., helping to keep the vapor region clear of liquid. Accordingly, the controller 760 can (e.g., in response to sensor measurements) adjust the shape and size of the vapor region by pivoting the actuator 762. This can be advantageous in allowing the vapor bubbles to rise and escape at uniform pressure and selectively resizing the vapor region to continue maintaining thin-film evaporation.

FIG. 8 is a perspective view of another actuatable two-phase immersion cooling device 810 (“the device 810”) configured in accordance with various embodiments of the present technology. The device 810 can include a base 812, a plurality of blades 820, a controller 860 (illustrated schematically), and an actuator 862. Like the blades 220 of FIG. 2, the blades 820 can be coupled to and extend from the base 812 and include microfeatures 830 that define microchannels 840. In the illustrated embodiment, the actuator 862 includes multiple fins 864 each positioned in between adjacent blades 820 and/or adjacent to one of the blades 820.

In operation, the controller 860 can operate the actuator 862 to move left or right along the length of the blades 820. As the actuator 862 moves, leading edges 865 of the individual fins 864 also move and define a variable vapor region 824. As shown, the leading edges 865 are curved such that the vapor region 824 is narrow at the bottom and wider at the top. Accordingly, fewer vapor bubbles may be generated at the bottom than at the top, allowing the vapor bubbles to rise through and escape more easily. Accordingly, the controller 860 can (e.g., in response to sensor measurements) adjust the shape and size of the vapor region 824 by moving the actuator 862.

Referring to FIGS. 7A-8 together, the actuatable devices 710, 810 can be advantageous the passive devices (e.g., the device 210 of FIG. 2) in various circumstances. For example, if a processing unit chip is cycling between high power consumption and low power consumption and thus the amount of heat generated is changing mid-operation, the vapor region may need to be resized to continue maintaining thin-film evaporation. More specifically, the vapor region may need to be downsized while the processing unit chip is operating at low power, and the vapor region may need to be expanded while the processing unit chip is operating at high power. In other words, by selectively resizing the vapor region, actuatable embodiments of the present technology can allow the vapor bubbles to rise and escape at uniform pressure sufficient to overcome the hydrostatic pressure, and thereby maintain thin-film evaporation across varying heat generation cycles.

It is appreciated that the devices 710, 810 of FIGS. 7A-8 are merely illustrative examples, and that other embodiments of the present technology can include fewer, additional, and/or alternative components. For example, the leading edges of the fins need not have the exact straight or curved profiles illustrated herein, and can have other geometric profiles. In particular, the specific profile of the leading edges of the fins can be selected based on, e.g., the heat-generating profile of the electronics to be cooled. As another example, while the devices 710, 810 are described above as actuatable, in some embodiments, the fins 764, 864 may be static or non-actuatable (e.g., the controllers 760, 860 may be omitted), and the geometries of the leading edges 765, 865 can be sufficient to help maintain the desired liquid and vapor regions.

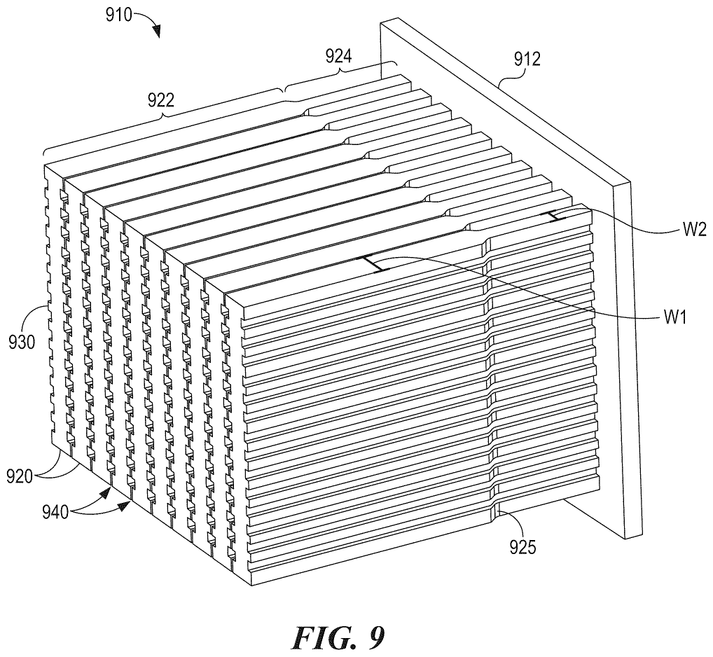

FIG. 9 is a perspective view of a variable-width two-phase immersion cooling device 910 (“the device 910”) configured in accordance with various embodiments of the present technology. The device 910 can include a base 912 and a plurality of blades 920. The blades 920 can be coupled to and extend from the base 912 and include microfeatures 930 that define microchannels 940. In the illustrated embodiment, distal portions of the blades 920 have a first width W1 that help define a liquid region 922, and proximal portions of the blades 920 have a second width W2 that help define a vapor region 924. The second width W2 can be narrower than the first width W1 such that the gaps between the blades 920 are wider at the vapor region 924 than at the liquid region 922. Also, as shown, the blades 920 can have a curved surface contour 925 that extends downward in a straight line and transitions between the liquid region 922 and the vapor region 924. In operation, the curved surface contour 925 can help remove low velocity points at the bottom of the vapor region 924.

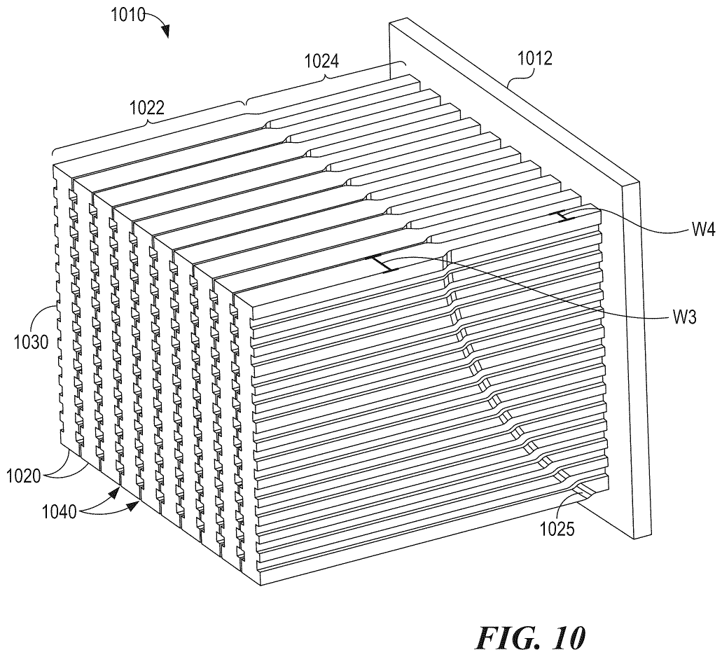

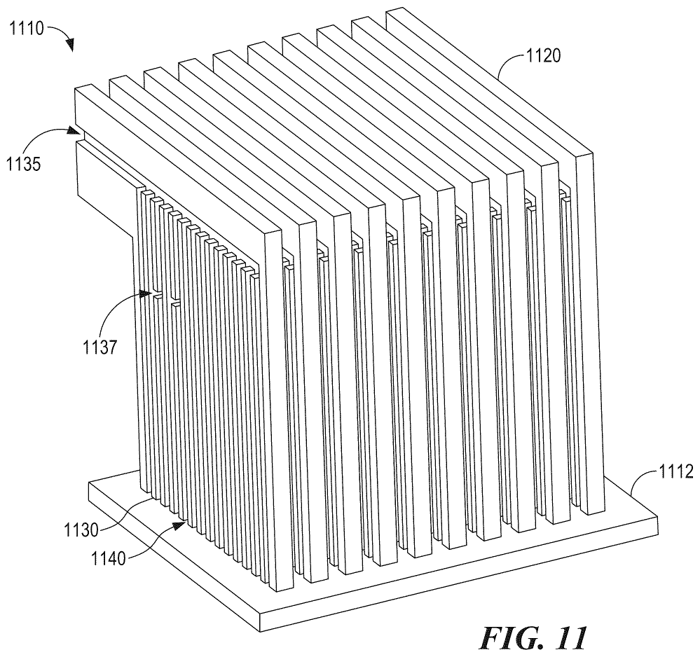

FIG. 10 is a perspective view of another variable-width two-phase immersion cooling device 1010 (“the device 1010”) configured in accordance with various embodiments of the present technology. The device 1010 can include a base 1012 and a plurality of blades 1020. The blades 1020 can be coupled to and extend from the base 1012 and include microfeatures 1030 that define microchannels 1040. In the illustrated embodiment, distal portions of the blades 1020 have a third width W3 that help define a liquid region 1022, and proximal portions of the blades 1020 have a fourth width W4 that help define a vapor region 1024. The fourth width W4 can be narrower than the third width W3 such that the gaps between the blades 1020 are wider at the vapor region 1024 than at the liquid region 1022. Also, as shown, the blades 1020 can have width narrowing regions that together form a curved surface contour 1025 that extends downward in a curved line and transitions between the liquid region 1022 and the vapor region 1024. In operation, the curved surface contour 1025 can help remove low velocity points at the bottom of the vapor region 1024.

FIG. 11 is a perspective view of a feeder two-phase immersion cooling device 1110 (“the device 1110”) configured in accordance with various embodiments of the present technology. The device 1110 can include a base 1112 and a plurality of blades 1120. The blades 1120 can be coupled to and extend from the base 1112 and include microfeatures 1130 that define microchannels 1140. Each of the blades 1120 can also include a feeder channel 1135 extending generally parallel to the base 1112 and fluidly coupled to the distal end of each microchannel 1140 on the side opposite the base 1112. In other words, the microchannels 1140 branch out from different portions along the length of the feeder channel 1135 in a direction perpendicular to the feeder channel 1135. In some embodiments, the device 1110 includes one or more channel segments 1137 fluidly coupling adjacent ones of the microchannels 1140.

In operation, the base 1112 can be coupled to electronics (not shown) such that the device 1110 is positioned above the electronics with respect to the direction of gravity. The feeder channel 1135 can help draw in the cooling fluid (in liquid phase) into the individual microchannels 1140, and the microfeatures 1130 can define a vapor region close to the base 1112. Accordingly, the device 1110 can maintain thin-film evaporation and the vapor bubbles generated can rise upward in a direction parallel to the microchannels 1140.

It is appreciated that the device 1110 of FIG. 11 is merely an illustrative example, and that other embodiments of the present technology can include fewer, additional, and/or alternative components. For example, the microchannels 1140 may be fluidly connected to one another via channel segments that extend perpendicular or at an angle relative to the microchannels 1140.

### III. Select Embodiments of a Method for Cooling Electronics

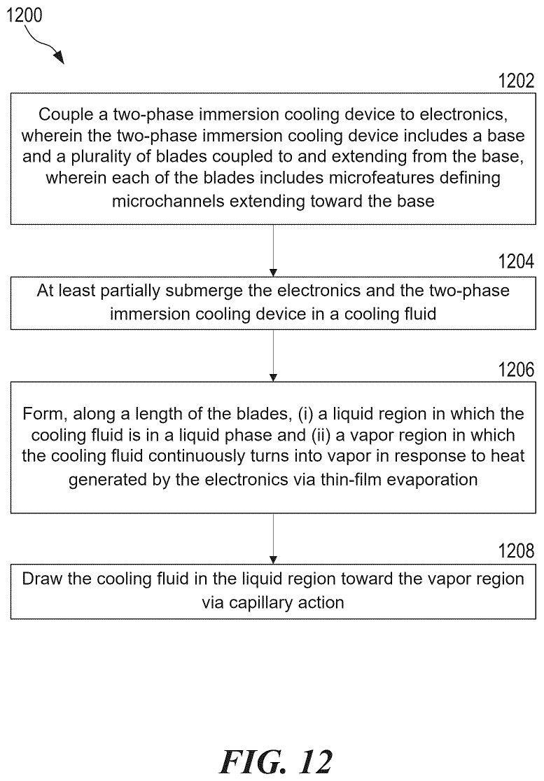

FIG. 12 is a flowchart illustrating a method for cooling electronics in accordance with various embodiments of the present technology. While the operations of the method 1200 are described below in a particular order, one or more of the operations can be performed in a different order or omitted, and the method 1200 can include additional and/or alternative operations. Additionally, although the method 1200 may be described below with reference to the embodiments of the present technology described herein, the method 1200 can be performed with other embodiments of the present technology.

The method 1200 begins at block 1202 by coupling a two-phase immersion cooling device to electronics. The two-phase immersion cooling device can include a base and a plurality of blades coupled to and extending from the base, and each of the blades can include microfeatures defining microchannels extending toward the base.

At block 1204, the method 1200 continues by at least partially submerging the electronics and the two-phase immersion cooling device in a cooling fluid.

At block 1206, the method 1200 continues by forming, along a length of the blades, (i) a liquid region in which the cooling fluid is in a liquid phase and (ii) a vapor region in which the cooling fluid continuously turns into vapor in response to heat generated by the electronics via thin-film evaporation. In some embodiments, forming comprises forming a meniscus of the cooling fluid on the base in individual ones of the microchannels, and the cooling fluid can continuously turn into vapor at an evaporating thin-film region of the meniscus .

At block 1208, the method 1200 continues by drawing the cooling fluid in the liquid region toward the vapor region via capillary action.

In some embodiments, the two-phase immersion cooling device further includes an actuator including fins disposed between individual ones of the blades, and leading edges of the fins can be configured to define a boundary of the vapor region. In such embodiments, the method 1200 can further comprise moving and/or rotating the fins to move the boundary of the vapor region.

### IV. EXAMPLES

The present technology is illustrated, for example, according to various aspects described below as numbered examples (1, 2, 3, etc.) for convenience. These are provided as examples and do not limit the present technology. It is noted that any of the dependent examples may be combined in any combination, and placed into a respective independent example. The other examples can be presented in a similar manner.
1. A two-phase immersion cooling device for cooling electronics, the device comprising:
   a base having a first side configured to be coupled to electronics and a second side opposite the first side; and
   a plurality of blades each coupled to and extending from the second side of the base along an axis substantially normal to an outer surface of the second side, wherein individual ones of the blades:
      include a first side coupled to the second side of the base, a second side opposite the first side, a third side extending between the first side and the second side, and a fourth side opposite the third side and extending between the first side and the second side of the individual ones of the blades, are spaced apart from one another such that fluid can flow therebetween, and include a plurality of microfeatures at the third side and/or fourth side of the
      respective blade, wherein the microfeatures increase an exposed surface area of the respective blade and adjacent microfeatures define microchannels therebetween, wherein individual ones of the microchannels extend along the axis and have a width between 1 femtometer and 1 millimeter,
   wherein the base and the blades are configured to be submerged in a cooling fluid.
2. The device of any of the examples herein, wherein the blades comprise cantilevered beams connected to one another only at the base.
3. The device of any of the examples herein, wherein the individual ones of the microfeatures comprise elongate protrusions having rectangular cross-sections.
4. The device of any of the examples herein, wherein the width of the individual ones of the microchannels is between 100 nanometers and 100 microns.
5. The device of any of the examples herein, wherein adjacent ones of the blades are spaced apart from one another by a gap between 20 microns and 1 millimeter.
6. The device of any of the examples herein, wherein individual ones of the blades have a length along the axis of at least 2 millimeters.
7. The device of any of the examples herein, wherein the base has a length between 10-30 millimeters and a thickness of no more than 5 millimeters.
8. The device of any of the examples herein, wherein individual ones of the blades includes the microfeatures on both the third side and the fourth side of the respective blade.
9. The device of any of the examples herein, wherein the device is configured to be oriented such that the blades lie along planes substantially parallel to a direction of gravity.
10. The device of any of the examples herein, wherein the device does not include thermoelectric components.
11. The device of any of the examples herein, further comprising:
   an actuator including fins disposed between individual ones of the blades; and
   a controller operably coupled to the actuator and configured to move and/or rotate the fins relative to the blades.
12. The device of any of the examples herein, wherein the individual ones of the blades have a first width along a first length portion thereof and a second width along a second length portion thereof, wherein the first length portion is closer to the base than the second length portion, and wherein the second width is greater than the first width.
13 The device of any of the examples herein, wherein the individual ones of the blades have width-narrowing regions that together form a curved surface contour that extends in a curved line.
14 The device of any of the examples herein, wherein the axis is a first axis, wherein each of the blades further includes a feeder channel extending along a second axis substantially perpendicular to the first axis, and wherein individual ones of the microchannels extend between the feeder channel and the base.
15. The device of any of the examples herein, wherein each of the blades further includes channel segments fluidly coupling adjacent ones of the microchannels.
16 The device of any of the examples herein, wherein individual ones of the blades are composed of copper.
17. A two-phase immersion cooling device for cooling electronics at least partially submerged in a cooling fluid, the device comprising:
   a base having a first side configured to be coupled to electronics and a second side opposite the first side; and
   a plurality of blades coupled to and extending from the second side of the base, wherein each of the blades includes microfeatures defining microchannels extending toward the base,
   wherein, in operation and when the device is submerged in the cooling fluid, the microfeatures—
      define (i) a liquid region in which the cooling fluid is in a liquid phase and (ii) a vapor region in which the cooling fluid continuously turns into vapor via thin-film evaporation in response to heat generated by the electronics, and
      draw the cooling fluid in the liquid region toward the vapor region via capillary action.
18. The device of any of the examples herein, wherein, in operation:
   the microfeatures form a meniscus of the cooling fluid on the base in individual ones of the microchannels, and
   the cooling fluid continuously turns into vapor at an evaporating thin-film region of the meniscus.
19. The device of any of the examples herein, wherein, in operation, the microchannels in the liquid region are filled with the cooling fluid in the liquid phase.
20. The device of any of the examples herein, wherein, in operation, the device does not induce boiling of the cooling fluid.
21. The device of any of the examples herein, further comprising:
   an actuator including fins disposed between individual ones of the blades, wherein leading edges of the fins are configured to define a boundary of the vapor region; and
   a controller operably coupled to the actuator and configured to move and/or rotate the fins to move the boundary of the vapor region.
22. The device of any of the examples herein, wherein each of the blades have a first width in the liquid region and a second width in the vapor region, wherein the second width is less than the first width.
23. A two-phase immersion cooling system for cooling electronics, the system comprising:
   an immersion cooling tank configured to be filled with a cooling fluid and to receive the electronics therein; and
   a two-phase immersion cooling device configured to be coupled to the electronics and submerged in the cooling fluid, wherein the two-phase immersion cooling device includes a base and a plurality of blades coupled to the base, and wherein each of the blades includes microfeatures that define microchannels extending toward the base and, when the two-phase immersion cooling device is submerged in the cooling fluid—define
      a liquid region in which the cooling fluid is in a liquid phase and a vapor region in which the cooling fluid continuously turns into vapor via thin-film evaporation in response to heat generated by the electronics, and
      draw the cooling fluid in the liquid region toward the vapor region via capillary action.
24. The system of any of the examples herein, wherein the base of the two-phase immersion cooling device is configured to be attached to a processing unit chip of the electronics.
25. The system of any of the examples herein, further comprising a plurality of two-phase immersion cooling devices including the two-phase immersion cooling device, wherein the two-phase immersion cooling devices are configured to be attached to corresponding ones of processing unit chips of the electronics.
26. The system of any of the examples herein, wherein, when the two-phase immersion cooling device is coupled to the electronics, the blades are oriented along planes parallel to a direction of gravity such that the vapor generated can rise through gaps in between adjacent ones of the blades.
27. The system of any of the examples herein, further comprising:
   an actuator coupled to the electronics; and
   a controller operably coupled to the actuator and configured to control the actuator to lift or lower the electronics within the immersion cooling tank to decrease or increase a hydrostatic pressure around the electronics.
28. A method for cooling electronics, the method comprising:
   coupling a two-phase immersion cooling device to electronics, wherein the two-phase immersion cooling device includes a base and a plurality of blades coupled to and extending from the base, wherein each of the blades includes microfeatures defining microchannels extending toward the base;
   at least partially submerging the electronics and the two-phase immersion cooling device in a cooling fluid;
   forming, along a length of the blades, (i) a liquid region in which the cooling fluid is in a liquid phase and (ii) a vapor region in which the cooling fluid continuously turns into vapor in response to heat generated by the electronics via thin-film evaporation; and
   drawing the cooling fluid in the liquid region toward the vapor region via capillary action.
29. The method of any of the examples herein, wherein forming comprises forming a meniscus of the cooling fluid on the base in individual ones of the microchannels, and wherein the cooling fluid continuously turns into vapor at an evaporating thin-film region of the meniscus.
30. The method of any of the examples herein, wherein the two-phase immersion cooling device further includes an actuator including fins disposed between individual ones of the blades, wherein leading edges of the fins are configured to define a boundary of the vapor region, and wherein the method further comprises moving and/or rotating the fins to move the boundary of the vapor region.

### V. Conclusion

It will be apparent to those having skill in the art that changes may be made to the details of the above-described embodiments without departing from the underlying principles of the present disclosure. In some cases, well known structures and functions have not been shown or described in detail to avoid unnecessarily obscuring the description of the embodiments of the present technology. Although steps of methods may be presented herein in a particular order, alternative embodiments may perform the steps in a different order. Similarly, certain aspects of the present technology disclosed in the context of particular embodiments can be combined or eliminated in other embodiments. Furthermore, while advantages associated with certain embodiments of the present technology may have been disclosed in the context of those embodiments, other embodiments can also exhibit such advantages, and not all embodiments need necessarily exhibit such advantages or other advantages disclosed herein to fall within the scope of the technology. Accordingly, the disclosure and associated technology can encompass other embodiments not expressly shown or described herein, and the invention is not limited except as by the appended claims.

To the extent any material incorporated herein by reference conflicts with the present disclosure, the present disclosure controls. Where the context permits, singular or plural terms may also include the plural or singular term, respectively. For example, throughout this disclosure, the singular terms “a,” “an,” and “the” include plural referents unless the context clearly indicates otherwise. Moreover, unless the word “or” is expressly limited to mean only a single item exclusive from the other items in reference to a list of two or more items, then the use of “or” in such a list is to be interpreted as including (a) any single item in the list, (b) all of the items in the list, or (c) any combination of the items in the list. Furthermore, as used herein, the phrase “and/or” as in “A and/or B” refers to A alone, B alone, and both A and B. Additionally, the terms “comprising,” “including,” “having,” and “with” are used throughout to mean including at least the recited feature(s) such that any greater number of the same features and/or additional types of other features are not precluded. Moreover, as used herein, the phrases “based on,” “depends on,” “as a result of,” and “in response to” shall not be construed as a reference to a closed set of conditions. For example, a step that is described as “based on condition A” may be based on both condition A and condition B without departing from the scope of the present disclosure. In other words, as used herein, the phrase “based on” shall be construed in the same manner as the phrase “based at least in part on” or the phrase “based at least partially on.”

As used herein, the use of relative terminology, such as “about”, “approximately”, “substantially” and the like refer to the stated value plus or minus ten percent. For example, the use of the term “about 100” refers to a range of from 90 to 110, inclusive. In instances in which the context requires otherwise and/or relative terminology is used in reference to something that does not include a numerical value, the terms are given their ordinary meaning to one skilled in the art. Additionally, all ranges disclosed herein are to be understood to encompass the endpoints, and any and all subranges subsumed therein. For example, a range of “1 to 10” includes any and all subranges between (and including) the minimum value of 1 and the maximum value of 10 (e.g., any and all subranges having a minimum value of equal to or greater than 1 and a maximum value of equal to or less than 10, such as 5.5 to 10).

Spatially relative terms (e.g., “beneath,” “below,” “over,” “under,” “above,” “upper,” “top,” “bottom,” “left,” “right,” “center,” “middle,” and the like) may be used herein for ease of description to describe one element's or feature's relationship relative to one or more other elements or features as illustrated in the figures. It will be understood that the spatially relative terms are intended to encompass different orientations of a device or system in use or operation, in addition to the orientation depicted in the figures. For example, if a device or system illustrated in the figures is rotated, turned, or flipped about a horizontal axis, elements or features described as “below” or “beneath” or “under” one or more other elements or features may then be oriented “above” the one or more other elements or features. Thus, the exemplary terms “below” and “under” are non-limiting and can encompass both an orientation of above and below. The device or system may additionally, or alternatively, be otherwise oriented (e.g., rotated ninety degrees about a vertical axis, or at other orientations) than illustrated in the figures, and the spatially relative descriptors used herein are interpreted accordingly. In addition, it will also be understood that when an element is referred to as being “between” two other elements, it can be the only element between the two other elements, or one or more intervening elements may also be present.

The disclosure set forth above is not to be interpreted as reflecting an intention that any claim or example requires more features than those expressly recited in that claim or example. Rather, as the preceding examples and the following claims reflect, inventive aspects lie in a combination of fewer than all features of any single foregoing disclosed embodiment. Thus, the preceding examples and the following claims are hereby expressly incorporated into the Detailed Description, with each claim standing on its own as a separate embodiment. This disclosure includes all permutations of the independent claims with their dependent claims.

1. A two-phase immersion cooling device for cooling electronics, the device comprising:
a base having a first side configured to be coupled to electronics and a second side opposite the first side; and
a plurality of blades each coupled to and extending from the second side of the base along an axis substantially normal to an outer surface of the second side, wherein individual ones of the blades:
include a first side coupled to the second side of the base, a second side opposite the first side, a third side extending between the first side and the second side, and a fourth side opposite the third side and extending between the
are spaced apart from one another such that fluid can flow therebetween, and
include a plurality of microfeatures at the third side and/or fourth side of the respective blade, wherein the microfeatures increase an exposed surface area of the respective blade and adjacent microfeatures define microchannels therebetween, wherein individual ones of the microchannels extend along the axis and have a width between 1 femtometer and 1 millimeter,
wherein the base and the blades are configured to be submerged in a cooling fluid.

2. The device of claim 1, wherein the blades comprise cantilevered beams connected to one another only at the base.

3. The device of claim 1, wherein the individual ones of the microfeatures comprise elongate protrusions having rectangular cross-sections.

4. The device of claim 1, wherein the width of the individual ones of the microchannels is between 100 nanometers and 100 microns.

5. The device of claim 1, wherein adjacent ones of the blades are spaced apart from one another by a gap between 20 microns and 1 millimeter.

6. The device of claim 1, wherein individual ones of the blades have a length along the axis of at least 2 millimeters.

7. The device of claim 1, wherein the base has a length between 10-30 millimeters and a thickness of no more than 5 millimeters.

8. The device of claim 1, wherein individual ones of the blades includes the microfeatures on both the third side and the fourth side of the respective blade.

9. The device of claim 1, wherein the device is configured to be oriented such that the blades lie along planes substantially parallel to a direction of gravity.

10. The device of claim 1, wherein the device does not include thermoelectric components.

11. The device of claim 1, further comprising:
an actuator including fins disposed between individual ones of the blades; and
a controller operably coupled to the actuator and configured to move and/or rotate the fins relative to the blades.

12. The device of claim 1, wherein the individual ones of the blades have a first width along a first length portion thereof and a second width along a second length portion thereof, wherein the first length portion is closer to the base than the second length portion, and wherein the second width is greater than the first width.

13. The device of claim 1, wherein the individual ones of the blades have width-narrowing regions that together form a curved surface contour that extends in a curved line.

14. The device of claim 1, wherein the axis is a first axis, wherein each of the blades further includes a feeder channel extending along a second axis substantially perpendicular to the first axis, and wherein individual ones of the microchannels extend between the feeder channel and the base.

15. The device of claim 1, wherein each of the blades further includes channel segments fluidly coupling adjacent ones of the microchannels.

16. The device of claim 1, wherein individual ones of the blades are composed of copper.

17. A two-phase immersion cooling device for cooling electronics at least partially submerged in a cooling fluid, the device comprising:
a base having a first side configured to be coupled to electronics and a second side opposite the first side; and
a plurality of blades coupled to and extending from the second side of the base, wherein each of the blades includes microfeatures defining microchannels extending toward the base,
wherein, in operation and when the device is submerged in the cooling fluid, the microfeatures—
define (i) a liquid region in which the cooling fluid is in a liquid phase and (ii) a vapor region in which the cooling fluid continuously turns into vapor via thin-film evaporation in response to heat generated by the electronics, and
draw the cooling fluid in the liquid region toward the vapor region via capillary action.

18. The device of claim 17, wherein, in operation:
the microfeatures form a meniscus of the cooling fluid on the base in individual ones of the microchannels, and
the cooling fluid continuously turns into vapor at an evaporating thin-film region of the meniscus.

19. The device of claim 17, wherein, in operation, the microchannels in the liquid region are filled with the cooling fluid in the liquid phase.

20. The device of claim 17, wherein, in operation, the device does not induce boiling of the cooling fluid.

21. The device of claim 17, further comprising:
an actuator including fins disposed between individual ones of the blades, wherein leading edges of the fins are configured to define a boundary of the vapor region; and
a controller operably coupled to the actuator and configured to move and/or rotate the fins to move the boundary of the vapor region.

22. The device of claim 17, wherein each of the blades have a first width in the liquid region and a second width in the vapor region, wherein the second width is less than the first width.

23. A two-phase immersion cooling system for cooling electronics, the system comprising:
an immersion cooling tank configured to be filled with a cooling fluid and to receive the electronics therein; and
a two-phase immersion cooling device configured to be coupled to the electronics and submerged in the cooling fluid, wherein the two-phase immersion cooling device includes a base and a plurality of blades coupled to the base, and wherein each of the blades includes microfeatures that define microchannels extending toward the base and, when the two-phase immersion cooling device is submerged in the cooling fluid—
define a liquid region in which the cooling fluid is in a liquid phase and a vapor region in which the cooling fluid continuously turns into vapor via thin-film evaporation in response to heat generated by the electronics, and
draw the cooling fluid in the liquid region toward the vapor region via capillary action.

24. The system of claim 23, wherein the base of the two-phase immersion cooling device is configured to be attached to a processing unit chip of the electronics.

25. The system of claim 23, further comprising a plurality of two-phase immersion cooling devices including the two-phase immersion cooling device, wherein the two-phase immersion cooling devices are configured to be attached to corresponding ones of processing unit chips of the electronics.

26. The system of claim 23, wherein, when the two-phase immersion cooling device is coupled to the electronics, the blades are oriented along planes parallel to a direction of gravity such that the vapor generated can rise through gaps in between adjacent ones of the blades.

27. The system of claim 23, further comprising:
an actuator coupled to the electronics; and
a controller operably coupled to the actuator and configured to control the actuator to lift or lower the electronics within the immersion cooling tank to decrease or increase a hydrostatic pressure around the electronics.

28. A method for cooling electronics, the method comprising:
coupling a two-phase immersion cooling device to electronics, wherein the two-phase immersion cooling device includes a base and a plurality of blades coupled to and extending from the base, wherein each of the blades includes microfeatures defining microchannels extending toward the base;
at least partially submerging the electronics and the two-phase immersion cooling device in a cooling fluid;
forming, along a length of the blades, (i) a liquid region in which the cooling fluid is in a liquid phase and (ii) a vapor region in which the cooling fluid continuously turns into vapor in response to heat generated by the electronics via thin-film evaporation; and
drawing the cooling fluid in the liquid region toward the vapor region via capillary action.

29. The method of claim 28, wherein forming comprises forming a meniscus of the cooling fluid on the base in individual ones of the microchannels, and wherein the cooling fluid continuously turns into vapor at an evaporating thin-film region of the meniscus.

30. The method of claim 28, wherein the two-phase immersion cooling device further includes an actuator including fins disposed between individual ones of the blades, wherein leading edges of the fins are configured to define a boundary of the vapor region, and wherein the method further comprises moving and/or rotating the fins to move the boundary of the vapor region.
